(19) United States
(12) Patent Application Publication
(10) Pub. No.: US 2005/0167733 A1
(43) Pub. Date: Aug. 4, 2005

(54) Memory device and method of manufacture

(75) Inventors: William A. McGee, San Jose, CA (US); Bruce Alan Gieseke, San Jose, CA (US); Ognjen Milic-Strkalj, San Jose, CA (US)

Correspondence Address: THE CAVANAGH LAW FIRM, VIAD CORPORATE CENTER, 1850 NORTH CENTRAL AVENUE, SUITE 2400, PHOENIX, AZ, 85004, US

(73) Assignee: ADVANCED MICRO DEVICES, INC.

(21) Appl. No.: 10/770,887

(22) Filed: Feb. 2, 2004

(51) Int. Cl. H01L 29/788; H01L 29/76; H01L 31/062; H01L 29/94

(52) U.S. Cl. 257/316; 257/315; 257/393; 257/401

(57) ABSTRACT

A memory cell and a method for manufacturing the memory cell. The memory cell is constructed so that it has a ratio of a dimension in the direction of the bit lines to a dimension in the direction of the word line of less than one. The bit lines are formed from the first metallization system of the memory cell, which is the metallization system nearest the surface of the substrate and the silicide regions of the memory cell. The word line is formed from a metallization system above the first metallization system. Thus, the bit lines are positioned vertically between the substrate surface and the word line.

### FIELD OF THE INVENTION

The present invention relates, in general, to a semiconductor device and, more particularly, to a semiconductor memory device.

### BACKGROUND OF THE INVENTION

Memory devices are used in a variety of electronic systems including computers, cellular phones, pagers, personal digital assistants, avionic systems, automotive systems, industrial control systems, appliances, etc. Depending on the particular system configuration, the memory devices may be either non-volatile (i.e., flash) or volatile (i.e., dynamic or static). A non-volatile memory device retains the information stored therein when the device is turned off or power is removed. A volatile memory device, on the other hand, does not retain the information when the device is turned off.

A memory device comprises a plurality of memory cells arranged in an array of columns and rows. Static memory cells typically have a storage element coupled between a pair of pass transistors. Each column of memory cells has a pass transistor coupled to a bit line and another pass transistor coupled to a complementary bit line. More particularly, one of the pair of pass transistors in a particular column of memory cells has an electrode coupled to a bit line and the other transistor of the pair of transistors has an electrode coupled to the complementary bit line. The gate terminals of the pair of pass transistors in a particular row of memory cells are coupled to a word line corresponding to that row of memory cells. A memory cell is selected by applying a select or address signal to its associated word line. Information is read from or stored to the selected memory cell by applying the appropriate signals on the bit line and the complementary bit line.

As the demand for storage capacity in a memory device has increased, memory device manufacturers have increased the cell density of the memory devices. Because the bit lines are connected to every memory cell in a particular column of memory cells, increasing the number of memory cells results in an increase in the length of the bit lines. The increased bit line length has an increased parasitic capacitance and parasitic resistance. This increase in bit line capacitance and resistance lowers the speeds of the memory devices.

In addition, the increase in memory cell density increases the capacitive coupling between bit lines and word lines, which causes erroneous read or write operations.

Accordingly, what is needed is memory cell having lower bit line capacitance and lower capacitive coupling between bit lines and word lines and a method for manufacturing the memory cell.

### SUMMARY OF THE INVENTION

The present invention satisfies the foregoing need by providing a memory device having a layout configuration that allows a reduction in bit line capacitance and a method for manufacturing the memory device. In accordance with one aspect, the present invention comprises a memory element including a memory cell having an aspect ratio less than one. The aspect ratio is a ratio of a first dimension of the memory cell to a second dimension of the memory cell, wherein the first dimension is in the direction of a pair of bit lines of the memory element and the second dimension is in the direction of a word line of the memory element.

In accordance with another aspect, the present invention includes a semiconductor substrate having a major surface. A memory cell is formed from the substrate, wherein the memory cell has at least one silicided portion. A first layer of dielectric material is disposed over the major surface and the at least one silicided portion. A bit line metallization system is disposed over the first layer of dielectric material. A word line metallization system is disposed over the bit line metallization system.

In accordance with yet another aspect, the present invention comprises a method for manufacturing a memory device. A substrate is provided and first, second, third, and fourth doped regions are formed in the substrate. The first and third doped regions are of a first conductivity type and the second and fourth doped regions are of a second conductivity type. The first and second doped regions are formed to abut each other and the third and fourth doped regions are formed to abut each other. The first and second doped regions are spaced apart from the third and forth doped regions. A first gate structure is formed over a portion of the first doped region. A second gate structure is formed over another portion of the first doped region and over the second doped region. A dopant of the second conductivity type is implanted into the portions of the first doped region adjacent the first and second gate structures. A dopant of the first conductivity type is implanted into the portions of the first doped region adjacent the first and second gate structures. A dopant of the first conductivity type is implanted into the portions of the second doped region adjacent the second gate structure. A bit line interconnect layer is formed over the substrate, wherein the bit line interconnect layer is electrically coupled to the portion of the first doped region adjacent a first side of the first gate structure. A word line interconnect is formed over the bit line interconnect layer, wherein the word line interconnect layer is electrically coupled to the first gate structure.

### BRIEF DESCRIPTION OF THE DRAWINGS

The present invention will be better understood from a reading of the following detailed description, taken in conjunction with the accompanying drawing figures, in which like reference numbers designate like elements and in which:

FIG. 1 is a top view of a memory cell at a beginning stage of manufacture in accordance with an embodiment of the present invention;

FIG. 2 is a cross-sectional side view taken along section line 2-2 of FIG. 1;

FIG. 3 is a cross-sectional side view taken along section line 3-3 of FIG. 1;

FIG. 4 is a cross-sectional side view taken along section line 4-4 of FIG. 1;

FIG. 5 is a top view of the memory cell of FIGS. 1-4 further along in manufacture;

FIG. 6 is a cross-sectional side view taken along section line 6-6 of FIG. 5;

FIG. 7 is a cross-sectional side view taken along section line 7-7 of FIG. 5;

FIG. 8 is a cross-sectional side view taken along section line 8-8 of FIG. 5;

FIG. 9 is a top view of the memory cell of FIGS. 5-8 further along in manufacture;

FIG. 10 is a cross-sectional side view taken along section line 10-10 of FIG. 9;

FIG. 11 is a cross-sectional side view taken along section line 11-1 of FIG. 9;

FIG. 12 is a cross-sectional side view taken along section line 12-12 of FIG. 9;

FIG. 13 is a top view of the memory cell of FIGS. 9-12 further along in manufacture;

FIG. 14 is a cross-sectional side view taken along section line 14-14 of FIG. 13;

FIG. 15 is a cross-sectional side view taken along section line 15-15 of FIG. 13;

FIG. 16 is a cross-sectional side view taken along section line 16-16 of FIG. 13;

FIG. 17 is a top view of the memory cell of FIGS. 13-16 further along in manufacture;

FIG. 18 is a cross-sectional side view taken along section line 18-18 of FIG. 17;

FIG. 19 is a cross-sectional side view taken along section line 19-19 of FIG. 17;

FIG. 20 is a cross-sectional side view taken along section line 20-20 of FIG. 17; and

FIG. 21 is a schematic diagram of the memory cell of FIGS. 17-20.

### DETAILED DESCRIPTION

Generally, the present invention provides a memory element such as a 6T memory cell and a method for its manufacture. In accordance with an embodiment of the present invention, the memory cell has an aspect ratio less than approximately one, where the aspect ratio is defined as the ratio of the dimension of the memory cell in the direction the bit lines run to the dimension of the memory cell in the direction the word lines run. Preferably the aspect ratio is less than approximately 0.5. In an example where the bit lines run in the direction of the y-axis of a Cartesian coordinate system and the word lines run in the direction of the x-axis of the Cartesian coordinate system, the memory cells in accordance with present invention are wider and shorter than in conventional memory cells.

In addition, memory cells in accordance with the present invention are manufactured with the bit lines formed in the lowest level metallization system, i.e., the metallization system closest to the surface of the substrate and the silicide regions. Placing the bit lines in this metallization system lowers the parasitic capacitance associated with charging and discharging the bit lines. Further, memory cells in accordance with the present invention have uniquely shaped doped regions that allow forming an inverter and a pass gate in a first half of the memory cell and forming another inverter and another pass gate in a second half of the memory cell, wherein the first and second halves of the memory cells are laterally adjacent to each other. Because of the uniqueness of the shape of the doped regions, they are rotated by 180 degrees with respect to each other.

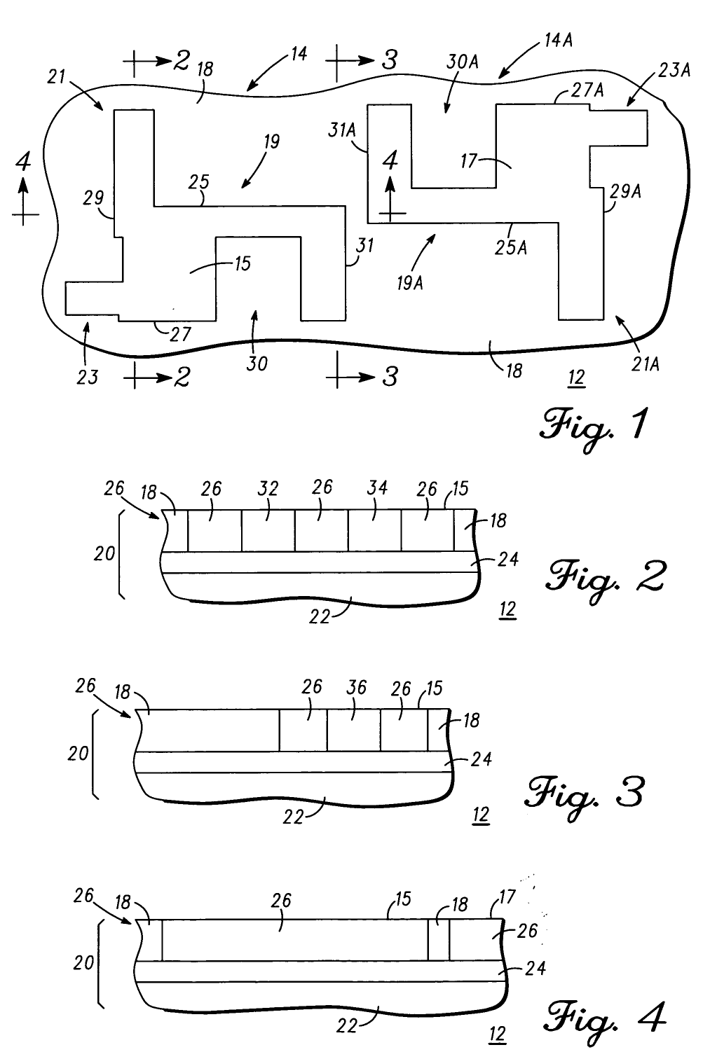

FIG. 1 is a top view of a portion of a memory cell 12 at a beginning stage of manufacture in accordance with an embodiment of the present invention. For the sake of clarity, FIG. 1 will be described in conjunction with FIGS. 2-4, which are cross-sectional side views taken along different portions of memory cell 12. More particularly, FIG. 2 is a cross-sectional side view of memory cell 12 taken along section line 2-2 of FIG. 1; FIG. 3 is a cross-sectional side view of memory cell 12 taken along section line 3-3 of FIG. 1; and FIG. 4 is a cross-sectional side view of memory cell 12 taken along section line 4-4 of FIG. 1. It should be understood that the cross-sectional side views of FIGS. 2-4 are taken at the same step in the manufacturing process. What is shown in FIG. 1 is a memory cell 12 having semiconductor regions 14 and 14A separated by a dielectric material 18. Semiconductor regions 14 and 14A can be regions of intrinsic silicon or they can be doped silicon material. Preferably, semiconductor regions 14 and 14A are formed from the silicon active layer of a Silicon-On-Insulator (SOI) substrate. Briefly referring to FIGS. 2-4, cross-sectional side views of an SOI substrate 20 are shown in which SOI substrate 20 comprises a silicon active layer 26 disposed on a layer of dielectric material 24 which is disposed on a body of semiconductor material 22. Silicon active layer 26 has a thickness ranging from that of a monolayer of silicon to approximately 1,000 Angstroms (Å) and dielectric layer 24 has a thickness ranging from about 100 Å to about 5000 Å. It should be understood that the type of substrate from which memory cell 12 is formed is not a limitation of the present invention. For example, memory cell 12 can be formed from a bulk silicon substrate, a germanium substrate, a silicon germanium substrate, a silicon-on-sapphire substrate, a compound semiconductor substrate, or the like.

Referring again to FIG. 1, silicon regions 14 and 14A are formed by patterning a masking layer (not shown) over silicon active layer 26 to cover the regions of silicon active layer 26 from which silicon regions 14 and 14A are formed. The exposed portions of silicon active layer 26 are removed to form trenches (not shown) that expose dielectric layer 24. The masking layer is removed and the trenches are filled with a dielectric material. By way of example, the dielectric material is silicon dioxide deposited in the trenches and over the remaining portions of silicon active layer 26. The dielectric material is planarized leaving dielectric material 18 and exposing silicon regions 14 and 14A which have surfaces 15 and 17, respectively. Preferably, silicon regions 14 and 14A have the same shape as each other but are rotated by 180 degrees with respect to each other. In other words, if silicon region 14A were rotated counter-clockwise by 180 degrees it would have the same shape and orientation as silicon region 14.

Silicon region 14 comprises three rectangular shaped regions 19, 21, and 23. Region 19 has opposing sides 25 and 27, opposing sides 29 and 31, and a U-shaped gap 30 that extends into silicon region 14 from side 27. U-shaped gap 30 may have rounded corners or it may have corners that meet at right angles. Region 21 is a rectangular extension region that extends from portions of sides 25 and 29 and is referred to as a pass transistor area. Region 23 is a rectangular extension region that extends from side 29 of region 19. The portion of region 19 between sides 25 and 27 and adjacent side 29 is referred to as a driver area.

Likewise, silicon region 14A comprises three rectangular shaped regions 19A, 21A, and 23A. Region 19A has opposing sides 25A and 27A, opposing sides 29A and 31A, and a U-shaped gap 30A that extends into silicon region 14A from side 27A. Like U-shaped gap 30, U-shaped gap 30A may have rounded corners or it may have corners that meet at right angles. Region 21A is a rectangular extension region that extends from a portion of side 25A and a portion of side 29A and is referred to as a pass transistor area. Region 23A is a rectangular extension region that extends from side 29A of region 19A. The portion of region 19A between sides 25A and 27A and adjacent side 29A is referred to as a driver area. Preferably, the width of the driver area is greater than the width of the pass transistor area. Because silicon regions 14 and 14A are rotated by 180 degrees with respect to each other, rectangular extension region 21 and U-shaped gap 30A face the same direction and rectangular extension region 21A and U-shaped gap 30 face the same direction. The direction faced by extension region 21 and U-shaped gap 30A is opposite from the direction faced by extension region 21A and U-shaped gap 30. Forming silicon regions 14 and 14A with U-shaped gaps 30 and 30A and rectangular shaped extensions 21, 23, 21A, and 23A, and rotating silicon regions 14 and 14A by 180 degrees with respect to each other, permits the formation of a 6T memory cell having an aspect ratio less than one.

Still referring to FIG. 1, a layer of photoresist (not shown) is patterned over silicon regions 14 and 14A and dielectric material 18 to expose the portions of silicon regions 14 and 14A which will be doped by a threshold voltage adjust implant for the N-channel transistors. The threshold voltage adjust implant is performed so that the implanted regions have a concentration of P-type dopants such as, for example, boron of about 1015 atoms per centimeter cubed (atoms/cm³). Briefly referring to FIG. 2, P-type threshold voltage adjust regions 32 and 34 are shown in silicon active layer 26 along section line 2-2. The layer of photoresist is removed and another layer of photoresist (not shown) is patterned over silicon regions 14 and 14A and dielectric material 18 to expose the portions of silicon regions 14 and 14A which will be doped by a threshold voltage adjust implant for the P-channel transistors. The threshold voltage adjust implant is performed so that the implanted regions have a concentration of N-type dopants such as, for example phosphorus, of about 10¹⁵ atoms/cm³. Briefly referring to FIG. 3, N-type threshold voltage adjust region 36 is shown in silicon active layer 26 along section line 3-3.

Briefly referring to FIG. 4, a portion of silicon active layer 26 taken along section line 4-4 is shown.

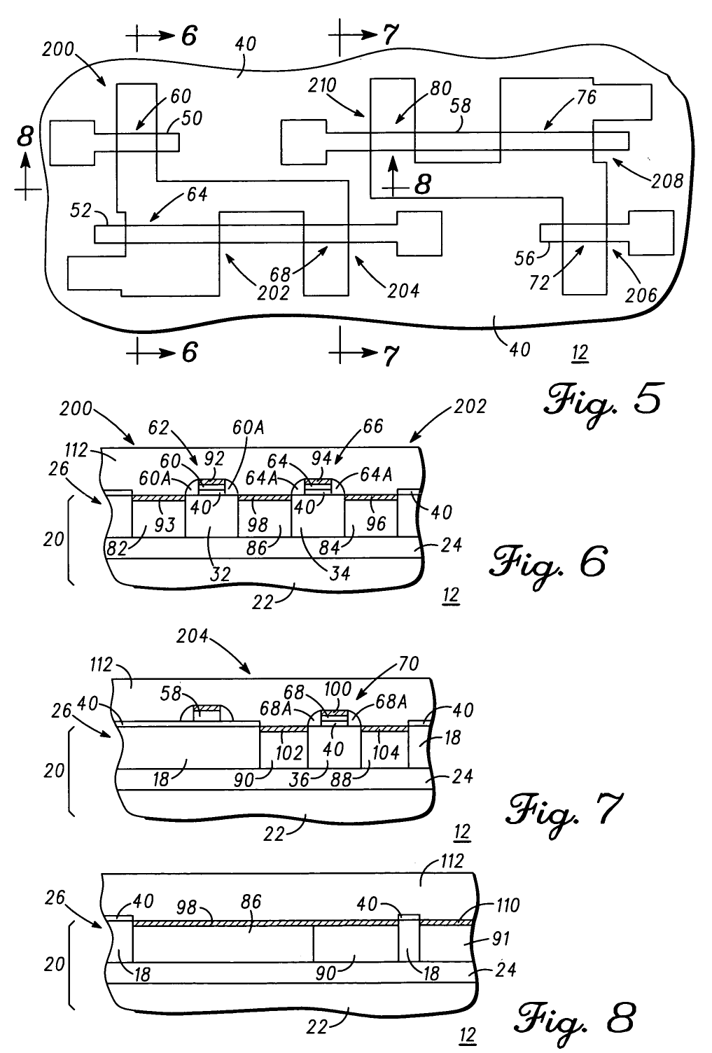

Referring now to FIG. 5, a top view of memory cell 12 is illustrated further along in manufacture. Similar to FIGS. 1-4, FIG. 5 will be described in conjunction with FIGS. 6-8, which are cross-sectional side views taken along different portions of memory cell 12 of FIG. 5. More particularly, FIG. 6 is a cross-sectional side view of memory cell 12 taken along section line 6-6 of FIG. 5 and illustrates the same portion of memory cell 12 as the cross-sectional side view of FIG. 2, but at a later stage of manufacture; FIG. 7 is a cross-sectional side view of memory cell 12 taken along section line 7-7 of FIG. 5 and illustrates the same portion of memory cell 12 as the cross-sectional side view of FIG. 3, but at a later stage of manufacture; and FIG. 8 is a cross-sectional side view of memory cell 12 taken along section line 8-8 of FIG. 5 and illustrates the same portion of memory cell 12 as the cross-sectional side view of FIG. 4, but at a later stage of manufacture. It should be understood that the cross-sectional side views of FIGS. 6-8 are taken at the same step in the manufacturing process.

A layer of dielectric material 40 having a thickness ranging from about 25 Å to about 200 Å is formed on surfaces 15 and 17 and on dielectric material 18. By way of example, dielectric layer 40 is silicon dioxide. Suitable techniques for forming dielectric layer 40 include thermal oxidation, chemical vapor deposition, and the like. A layer of polysilicon (not shown) having a thickness ranging from about 1,000 Å to about 2,000 Å is formed on dielectric layer 40 using, for example, a chemical vapor deposition technique. A layer of photoresist (not shown) is deposited on the polysilicon layer and patterned to form an etch mask.

The exposed portions of the polysilicon layer are etched using an etch chemistry that preferentially etches polysilicon. By way of example, the polysilicon layer is etched using an anisotropic Reactive Ion Etch (RIE) and an etchant species that is selective to photoresist. Optionally, dielectric material 40 may be anisotropically etched after etching the polysilicon layer. After etching, the remaining portions 50, 52, 56, and 58 of the polysilicon layer serve as gate fingers for memory cell 12. Gate fingers 50, 52, 56, and 58 are substantially parallel to each other. Methods for etching polysilicon and dielectric materials are well known to those skilled in the art. The photoresist etch mask is removed. It should be noted that after the anisotropic etch, portions of dielectric material 40 remain under gate fingers 50, 52, 56, and 58.

In silicon region 14, the portion 60 of gate finger 50 overlying surface 15 serves as a gate electrode of an N-channel transistor 200 and the portion of dielectric material 40 between gate electrode 60 and surface 15 serves as a gate dielectric material. Gate electrode 60 and the underlying gate dielectric material cooperate to form a gate structure 62 (shown in FIG. 6). The portion 64 of gate finger 52 overlying surface 15 serves as a gate electrode of an N-channel transistor 202 and the portion of dielectric material 40 between gate electrode 64 and surface 15 serves as a gate dielectric material. Gate electrode 64 and the underlying gate dielectric material cooperate to form a gate structure 66 (shown in FIG. 6). The portion 68 of gate finger 52 overlying surface 15 serves as a gate electrode of a P-channel transistor 204 and the portion of dielectric material 40 between gate electrode 68 and surface 15 serves as a gate dielectric material. Gate electrode 68 and the underlying gate dielectric material cooperate to form a gate structure 70 (shown in FIG. 7).

In silicon region 14A, the portion 72 of gate finger 56 overlying surface 17 serves as a gate electrode of an N-channel transistor 206 and the portion (not shown) of dielectric material 40 between gate electrode 72 and surface 17 serves as a gate dielectric material. Gate electrode 72 and the underlying gate dielectric material cooperate to form a gate structure. The portion 76 of gate finger 58 overlying surface 17 serves as a gate electrode of an N-channel transistor 208 and the portion of dielectric material 40 between gate electrode 76 and surface 17 serves as a gate dielectric material. Gate electrode 76 and the underlying gate dielectric material cooperate to form a gate structure. The portion 80 of gate finger 58 overlying surface 17 serves as a gate electrode of a P-channel transistor 210 and the portion of dielectric material 40 between gate electrode 80 and surface 17 serves as a gate dielectric material. Gate electrode 80 and the underlying gate dielectric material cooperate to form a gate structure.

A layer of dielectric material (not shown) is formed over gate electrodes 60, 64, 68, 72, 76, and 80, over the exposed portions of surfaces 15 and 17, and over the exposed portions of dielectric layer 40. The layer of dielectric material is anisotropically etched to form spacers adjacent gate electrodes 60, 64, 68, 72, 76, and 80. For the sake of clarity, the spacers are not illustrated in the top view shown in FIG. 5. However, spacers 60A, 64A, and 68A are shown as being along the sides of gate electrodes 60, 64, and 68, respectively, in the corresponding cross-sectional side views shown in FIGS. 6 and 7. A layer of photoresist (not shown) is patterned over silicon regions 14 and 14A and dielectric layer 40. The patterned layer of photoresist has openings that expose gate electrodes 60, 64, 72, and 76 and portions of silicon regions 14 and 14A. An N-type impurity material is implanted into the portions of memory cell 12 unprotected by photoresist to form the source and drain regions of transistors 200, 202, 206, and 208 and to dope gate electrodes 60, 64, 72, and 76. Source regions 82 and 84 of N-channel transistors 200 and 202, respectively, are shown in FIG. 6. It should be noted that transistors 200 and 202 share a common drain region which is identified by reference number 86 in FIG. 6. The layer of photoresist is removed.

Another layer of photoresist (not shown) is patterned over silicon regions 14 and 14A and dielectric layer 40. This layer of photoresist has openings that expose gate electrodes 68 and 80 and portions of silicon regions 14 and 14A. A P-type impurity material is implanted into the portions of memory cell 12 unprotected by the patterned layer of photoresist to form the source and drain regions of transistors 204 and 210 and to dope gate electrodes 68 and 80. Source region 88 and drain region 90 of P-channel transistor 204 are shown in FIG. 7. A portion of drain region 91 of P-channel transistor 210 is shown in FIG. 8. The layer of photoresist is removed. and the transistors are annealed by heating to a temperature ranging from approximately 800 degrees Celsius (° C.) to approximately 1,100° C.

A layer of refractory metal (not shown) is conformally deposited over the exposed portions of silicon surfaces 15 and 17 and gate fingers 50, 52, 56, and 58 and dielectric material 18. By way of example, the refractory metal is nickel having a thickness ranging from about 50 Å to about 150 Å. The refractory metal is heated to a temperature ranging between 350° C. and 500° C. The heat treatment causes the nickel to react with the silicon to form nickel silicide (NiSi) in all regions in which the nickel is in contact with silicon. Thus, nickel silicide is formed on gate electrodes 60, 64, 68, 72, 76, and 80, and the exposed portions of silicon regions 14 and 14A. Briefly referring to FIG. 6, nickel silicide layer 92 is formed from gate electrode 60, nickel silicide layer 93 is formed from source region 82, nickel silicide layer 94 is formed from gate electrode 64, nickel silicide layer 96 is formed from source region 84, and nickel silicide layer 98 is formed from drain region 86 of N-channel transistors 200 and 202.

Briefly referring to FIG. 7, nickel silicide layer 100 is formed from gate electrode 68, nickel silicide layer 102 is formed from drain region 90, and nickel silicide layer 104 is formed from source region 88 of P-channel transistor 204.

Briefly referring to FIG. 8, nickel silicide layer 98 is formed from drain regions 86 of N-channel transistors 200 and 202 and drain region 90 of P-channel transistor 204. Nickel silicide layer 110 is formed from source region 91 of P-channel transistor 210.

The portions of the nickel over dielectric layer 40 and the spacers remain unreacted. After formation of the nickel silicide layers, any unreacted nickel is removed. It should be understood that the type of silicide is not a limitation of the present invention. For example, other suitable silicides include titanium silicide (TiSi), platinum silicide (PtSi), cobalt silicide (CoSi₂), or the like. As those skilled in the art are aware, silicon is consumed during the formation of silicide and the amount of silicon consumed is a function of the type of silicide being formed.

A layer dielectric material 112 having a thickness ranging from about 500 Å to about 2,000 Å is formed on silicide layers 92, 93, 94, 96, 98, 100, 102, 104, and 110, over the exposed portions of dielectric material 40, and over the spacers. By way of example, dielectric layer 112 is oxide formed by decomposition of tetraethylorthosilicate (TEOS).

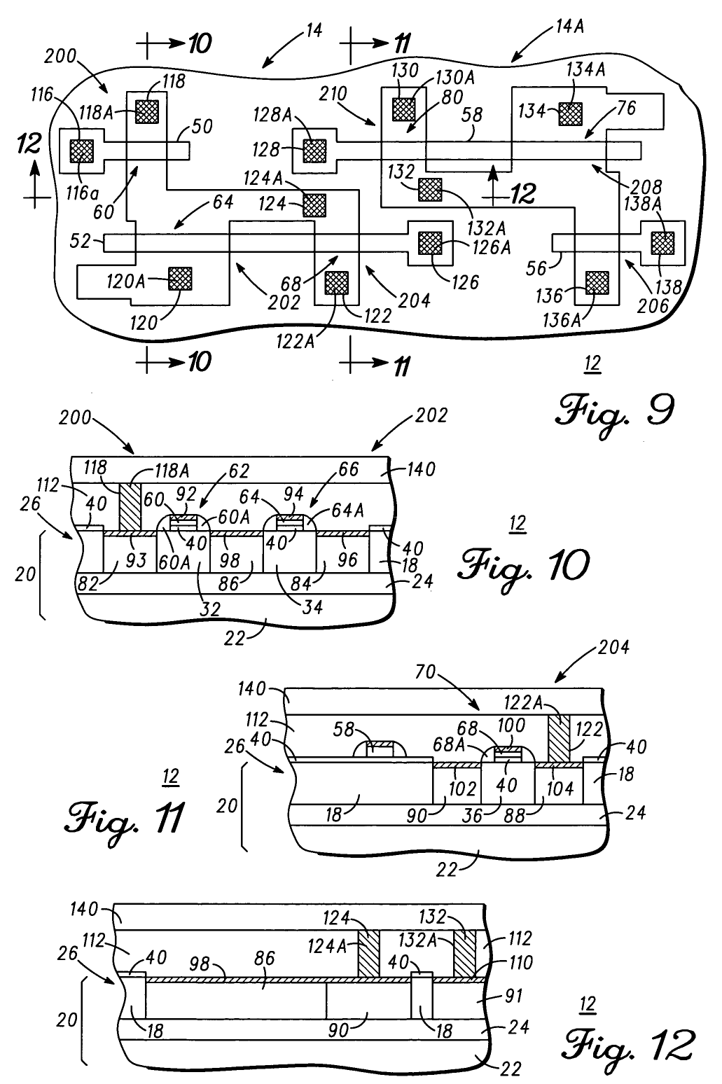

Referring now to FIG. 9, a top view of memory cell 12 is illustrated further along in manufacture. Similar to FIGS. 5-8, FIG. 9 will be described in conjunction with FIGS. 10-12, which are cross-sectional side views taken along different portions of memory cell 12 of FIG. 9. More particularly, FIG. 10 is a cross-sectional side view of memory cell 12 taken along section line 10-10 of FIG. 9 and illustrates the same portion of memory cell 12 as the cross-sectional side view of FIG. 6, but at a later stage of manufacture; FIG. 11 is a cross-sectional side view of memory cell 12 taken along section line 11-11 of FIG. 9 and illustrates the same portion of memory cell 12 as the cross-sectional side view of FIG. 7, but at a later stage of manufacture; and FIG. 12 is a cross-sectional side view of memory cell 12 taken along section line 12-12 of FIG. 9 and illustrates the same portion of memory cell 12 as the cross-sectional side view of FIG. 8, but at a later stage of manufacture. It should be understood that the cross-sectional side views of FIGS. 10-12 are taken at the same step in the manufacturing process.

Openings 116, 118, 120, 122, 124, 126, 128, 130, 132, 134, 136, and 138 are formed in oxide layer 112 to expose portions of the silicide layers. A conformal barrier layer (not shown) having a thickness ranging from about 5 Å to about 350 Å is formed on the portions of the silicide layers exposed by openings 116-138, the sidewalls of openings 116-138, and on oxide layer 112. A layer of electrically conductive material (not shown) is formed on the barrier layer. By way of example, the barrier layer is a tantalum layer formed using a technique such as, for example, Chemical Vapor Deposition (CVD), Plasma Enhanced Chemical Vapor Deposition (PECVD), sputtering, evaporation, or the like. A film or layer of an electrically conductive material (not shown) having a thickness ranging from about 10 Å to about 500 Å is formed on the barrier layer. By way of example, the electrically conductive material is copper and is plated on the barrier layer. Techniques for plating copper on a barrier layer are known to those skilled in the art. The electrically conductive layer is planarized to form contacts 116A, 118A, 120A, 122A, 124A, 126A, 128A, 130A, 132A, 134A, 136A, and 138A. Contacts 116A, 118A, and 124A serve as the gate, source, and drain contacts, respectively, of N-channel transistor 200. Contacts 126A, 120A, and 124A serve as the gate, source, and drain contacts, respectively, of N-channel transistor 202. Contacts 126A, 122A, and 124A serve as the gate, source, and drain contacts, respectively, of P-channel transistor 204. Similarly, contacts 138A, 136A, and 132A serve as the gate, source, and drain contacts, respectively, of N-channel transistor 206. Contacts 128A, 134A, and 132A serve as the gate, source, and drain contacts, respectively, of N-channel transistor 208. Contacts 128A, 130A, and 132A serve as the gate, source, and drain contacts, respectively, of P-channel transistor 210.

Briefly referring to FIGS. 10-12, cross-sectional side views of contacts 118A, 122A, 124A, and 132A are shown. A layer dielectric material 140 having a thickness ranging from about 500 Å to about 2,000 Å is formed on contacts 116A-138A and on dielectric material 112. By way of example, dielectric layer 140 is oxide formed by decomposition of tetraethylorthosilicate (TEOS).

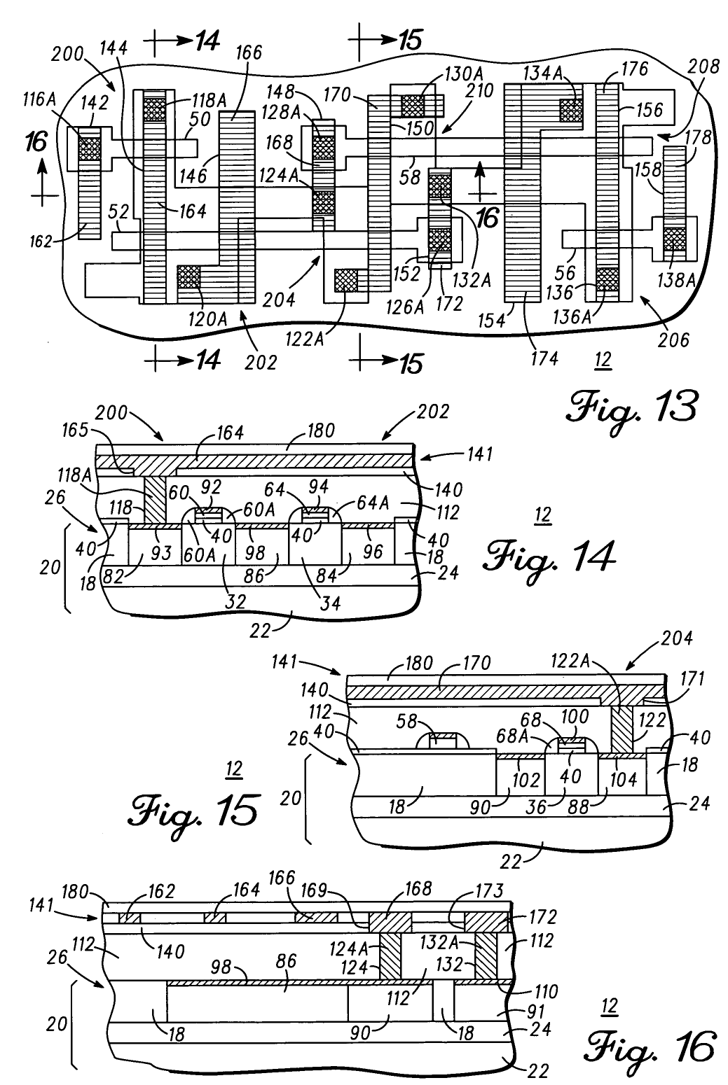

Referring now to FIG. 13, a top view of memory cell 12 is illustrated further along in manufacture. Similar to FIGS. 9-12, FIG. 13 will be described in conjunction with FIGS. 14-16, which are cross-sectional side views taken along different portions of memory cell 12 of FIG. 13. More particularly, FIG. 14 is a cross-sectional side view of memory cell 12 taken along section line 14-14 of FIG. 13 and illustrates the same portion of memory cell 12 as the cross-sectional side view of FIG. 10, but at a later stage of manufacture; FIG. 15 is a cross-sectional side view of memory cell 12 taken along section line 15-15 of FIG. 13 and illustrates the same portion of memory cell 12 as the cross-sectional side view of FIG. 11, but at a later stage of manufacture; and FIG. 16 is a cross-sectional side view of memory cell 12 taken along section line 16-16 of FIG. 13 and illustrates the same portion of memory cell 12 as the cross-sectional side view of FIG. 12, but at a later stage of manufacture. It should be understood that the cross-sectional side views of FIGS. 14-16 are taken at the same step in the manufacturing process.

A first conductive or interconnect layer 141 is formed over SOI substrate 20 using, for example, a Damascene process. More particularly, trenches 142, 144, 146, 148, 150, 152, 154, 156, and 158 and vias (not shown) are formed in dielectric layer 140. The vias are formed to uncover contacts 116A-138A. A conformal barrier layer (not shown) is formed on contacts 116A-138A, the sidewalls of the trenches and vias, and on oxide layer 140. A layer of electrically conductive material (not shown) is formed on the barrier layer and planarized to form interconnects 162, 164, 166, 168, 170, 172, 174, 176, and 178. Conductive layer 141 having vias and trenches filled with an electrically conductive material is referred to as a bit line metallization system. The barrier layer of electrically conductive layer 141 can be formed using techniques described with reference to FIGS. 9-12.

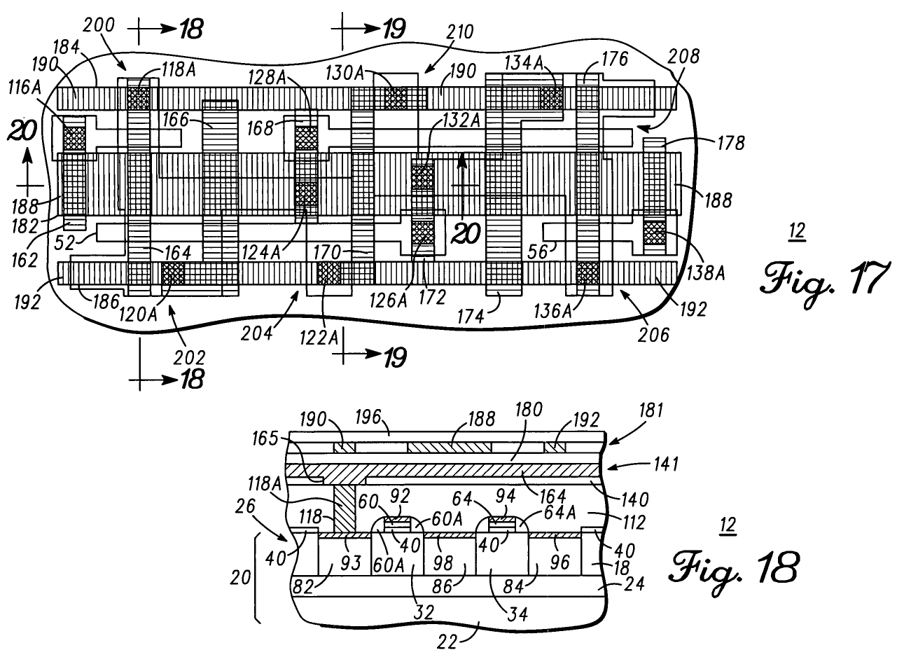

Interconnect 162 is coupled to gate finger 50, hence to gate electrode 60 of N-channel transistor 200, through contact 116A. Interconnect 162 includes a vertical extension or plug (not shown) extending to contact 116A. As described with reference to FIG. 17, interconnect 162 couples a word line to gate electrode 60. Briefly referring to FIG. 14, interconnect 164 is coupled to source region 82 through contact 118A. Interconnect 164 has a vertical extension or plug 165 extending to (i.e., in contact with) contact 118A. Interconnect 164 serves as a bit line interconnect for memory cell 12. Referring again to FIG. 13, interconnect 168 couples the drain of transistors 200 and 204 to the gate electrode 80 of transistor 210. Briefly referring to FIG. 16, interconnect 168 has a vertical extension or plug 169 extending to (i.e., in contact with) contact 124A.

More specifically referring to FIGS. 13, 14, and 16, interconnect 166 is coupled to source region 84 through contact 120A. Interconnect 166 serves as a power routing structure. In particular, interconnect 166 couples a source of operating potential, V_{SS}, to source region 84 of transistor 202. Interconnect 172 is coupled to gate finger 52 through contact 126A and to drain region 91 through plug 173 and contact 132A.

Referring now to FIGS. 13 and 15, interconnect 170 having a plug 171 couples source region 88 of P-channel transistor 204 to the source region of P-channel transistor 210. Interconnect 170 serves as a power routing structure. Thus, interconnect 170 couples a source of operating potential, VDD, to the source regions of P-channel transistors 204 and 210.

Referring now to FIG. 13, interconnect 178 is coupled to gate finger 56, hence to the gate electrode of N-channel transistor 206, through contact 138A. Interconnect 178 includes a vertical extension or plug (not shown) extending to contact 138A. As described with reference to FIG. 17, interconnect 178 couples a word line to gate electrode 72 of N-channel transistor 206. Interconnect 176 is coupled to the source region of N-channel transistor 206 through contact 136A. Interconnect 176 has a vertical extension or plug (not shown) extending to (i.e., in contact with) contact 136A. Interconnect 176 serves as a complementary bit line interconnect for memory cell 12. Interconnect 174 is coupled to the source region of N-channel transistor 208 through contact 134A. Interconnect 174 serves as a power routing structure. In particular, interconnect 174 couples a source of operating potential, V_{SS}, to the source region of N-channel transistor 208.

A layer dielectric material 180 having a thickness ranging from about 500 Å to about 2,000 Å is formed on interconnects 162-178 and on dielectric material 112. By way of example, dielectric layer 180 is oxide formed by decomposition of tetraethylorthosilicate (TEOS).

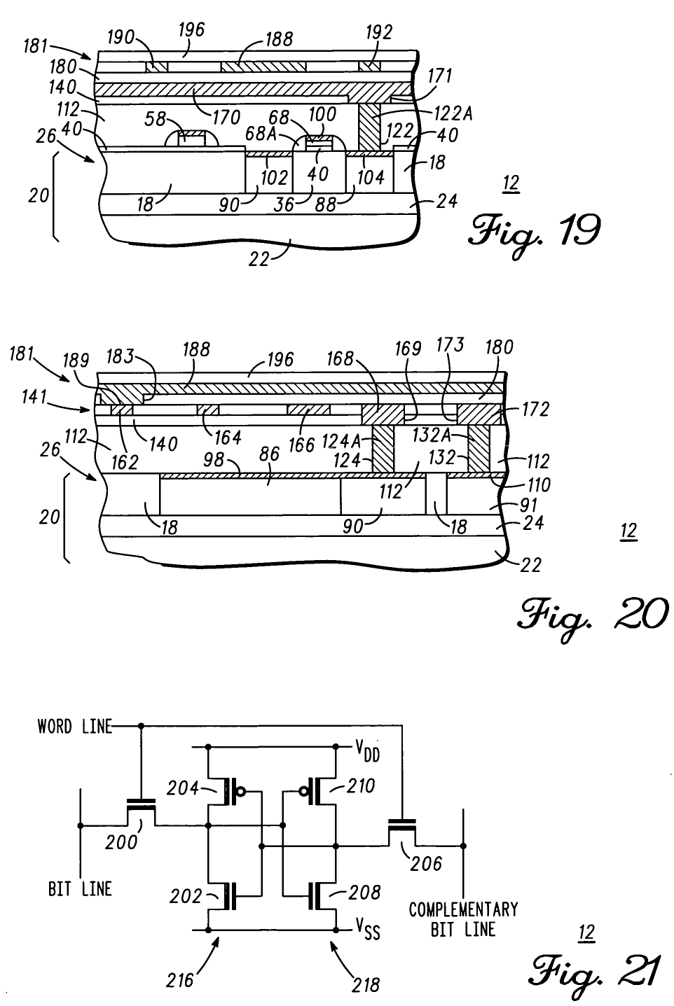

Referring now to FIG. 17, a top view of memory cell 12 is illustrated further along in manufacture. Similar to FIGS. 13-16, FIG. 17 will be described in conjunction with FIGS. 18-20, which are cross-sectional side views taken along different portions of memory cell 12 of FIG. 17. More particularly, FIG. 18 is a cross-sectional side view of memory cell 12 taken along section line 18-18 of FIG. 17 and illustrates the same portion of memory cell 12 as the cross-sectional side view of FIG. 14, but at a later stage of manufacture; FIG. 19 is a cross-sectional side view of memory cell 12 taken along section line 19-19 of FIG. 17 and illustrates the same portion of memory cell 12 as the cross-sectional side view of FIG. 15, but at a later stage of manufacture; and FIG. 20 is a cross-sectional side view of memory cell 12 taken along section line 20-20 of FIG. 17 and illustrates the same portion of memory cell 12 as the cross-sectional side view of FIG. 16, but at a later stage of manufacture. It should be understood that the cross-sectional side views of FIGS. 18-20 are taken at the same step in the manufacturing process.

A second conductive or interconnect layer 181 is formed over SOI substrate 20 using, for example, a Damascene process. More particularly, trenches 182, 184, and 186 and vias (not shown) are formed in dielectric layer 180. The vias in trench 182 are formed to uncover a portion of interconnects 162 and 178. One 183 of the vias is indicated in FIG. 20. The vias in trench 184 are formed to uncover interconnects 166 and 174 for coupling to the source of operating potential V_{SS}. The vias in trench 186 are formed to uncover interconnect 170 for coupling to the source of operating potential V_{DD}. A conformal barrier layer (not shown) having a thickness ranging from about 5 Å to about 350 Å is formed in the vias and trenches and on oxide layer 180. A layer of electrically conductive material (not shown) is formed on the barrier layer using techniques such as those described for forming interconnects 162-178 with reference to FIGS. 13-16. The electrically conductive layer is planarized to form interconnects 188, 190, and 192. Conductive layer 181 having vias and trenches filled with an electrically conductive material is referred to as a word line metallization system.

Interconnect 188 includes vertical extensions or plugs which contact interconnect layers 162 and 178. Briefly referring to FIG. 20, a vertical extension 189 is shown. Interconnect 188 serves as a word line for memory cell 12. Interconnect 190 is coupled to interconnect 170 and interconnect 192 is coupled to interconnects 166 and 174. Interconnects 190 and 192 serve as a bit line and a complementary bit line, respectively, for memory cell 12. An advantage of the present invention is that interconnects 190 and 192 provide shielding for word line 188.

A passivation layer 196 is formed on interconnects 188, 190, and 192 and oxide layer 180.

Referring now to FIG. 21, a schematic diagram of memory cell 12 is illustrated. Memory cell 12 comprises a pair of inverters 216 and 218 connected in a cross-coupled configuration. In addition, memory cell 12 includes passgate transistors 200 and 206 connected to inverters 216 and 218. Inverter 216 comprises P-channel transistor 204 and N-channel transistor 202 and inverter 218 comprises P-channel transistor 210 and N-channel transistor 208. The drain terminal of P-channel transistor 204 is connected to the drain terminal of N-channel transistor 202 to form a storage node and the gate terminal of P-channel transistor 204 is connected to the gate terminal of N-channel transistor 202 to form a gating node. The source terminal of P-channel transistor 204 is coupled for receiving a source of operating potential VDD and the source terminal of N-channel transistor 202 is coupled for receiving a source of operating potential V_{SS}. One current conducting electrode or terminal of N-channel transistor 200 is coupled to the drain terminals of transistors 204 and 202 and the other current conducting electrode of N-channel transistor 200 is coupled to the bit line of memory cell 12. The gate terminal of N-channel transistor 200 is coupled to the word line.

The drain terminal of P-channel transistor 210 is connected to the drain terminal of N-channel transistor 208 to form another storage node and the gate terminal of P-channel transistor 210 is connected to the gate terminal of N-channel transistor 208 to form another gating node. The commonly coupled gate terminals of transistors 210 and 208 are connected to the commonly connected drain terminals of transistors 204 and 202 and to the current conducting electrode of N-channel transistor 200. The commonly connected drain terminals of transistors 210 and 208 are connected to the commonly coupled gate terminals of transistors 204 and 202 and to a first current conducting terminal of N-channel transistor 206. The other current conducting electrode of N-channel transistor 206 is coupled to the bit line of memory cell 12 and the gate terminal of N-channel transistor 206 is coupled to the word line.

By now it should be appreciated that a memory cell and a method for manufacturing the memory cell having been provided. An advantage of memory cells in accordance with the present invention is that because their aspect ratios are less than one, the bit lines can be manufactured in the metallization systems closest to the surface and to the silicide layers. Further, bit lines manufactured in accordance with the present invention are shorter than conventional bit lines. This reduces the parasitic capacitances and resistances associated with the memory cells, which increases their access speeds. Another advantage of lowering the parasitic capacitances and resistances is that it lowers the supply levels required for operating the memory cells, which results in lower levels of power dissipation. Moreover, the present invention provides shielding for the bit lines which decreases the probability of an error occurring during the read and write operations.

Although certain preferred embodiments and methods have been disclosed herein, it will be apparent from the foregoing disclosure to those skilled in the art that variations and modifications of such embodiments and methods may be made without departing from the spirit and scope of the invention. For example, the substrate may be a bulk semiconductor material rather than a SOI substrate. It is intended that the invention shall be limited only to the extent required by the appended claims and the rules and principles of applicable law.

1. A memory element comprising a memory cell having an aspect ratio less than one, wherein the aspect ratio is a ratio of a first dimension of the memory cell to a second dimension of the memory cell, the first dimension in the direction of a bit line of the memory element and the second dimension in the direction of a word line of the memory element.

2. The memory element of claim 1, wherein the aspect ratio is less than 0.5.

3. The memory element of claim 1, wherein the memory cell is a 6T memory cell.

4. The memory element of claim 1, wherein the 6T memory cell comprises:
a first inverter having a gating node and a storage node;
a second inverter having a gating node and a storage node, wherein the gating node of the second inverter is coupled to the storage node of the first inverter and the storage node of the second inverter is coupled to the gating node of the first transistor;
a first pass transistor coupled to the storage node of the first inverter; and
a second pass transistor coupled to the storage node of the second inverter.

5. The memory element of claim 4, wherein the first pass transistor includes a control electrode coupled to the word line, a first current conducting electrode coupled to a first bit line of the pair of bit lines, and a second current conducting electrode coupled to the storage node of the first inverter.

6. The memory element of claim 5, wherein the second pass transistor includes a control electrode coupled to the word line, a first current conducting electrode coupled to a second bit line of the pair of bit lines, and a second current conducting electrode coupled to the storage node of the second inverter.

7. The memory element of claim 1, further comprising:
a semiconductor substrate having a major surface; and
a first metallization system disposed over the major surface, wherein the pair of bit lines comprise a portion of the first metallization system.

8. The memory element of claim 7, further including a second metallization system over the first metallization system, wherein the word line comprises a portion of the second metallization system.

9. The memory element of claim 8, further including a first shielding element adjacent one side of the word line.

10. The memory element of claim 9 further including a second shielding element adjacent an opposing side if the word line.

11. A memory element, comprising:
a substrate having a major surface;
a memory cell formed from the substrate, the memory cell including at least one silicided portion;
a first layer of dielectric material disposed over the major surface and the at least one silicided portion;
a bit line metallization system disposed over the first layer of dielectric material; and
a word line metallization system disposed over the bit line metallization system.

12. The memory element of claim 11, wherein the memory cell comprises a 6T memory cell.

13. The memory element of claim 12, wherein the 6T memory cell comprises:
a first doped region of a first conductivity type, the first doped region having a first pass transistor area and a first driver area;
a second doped region of a second conductivity type, the second doped region abutting the first doped region;
a first gate structure having first and second sides disposed over the first transistor area, wherein a first portion of the first pass transistor area adjacent the first side of the first gate structure is coupled to a first bit line; and
a second gate structure having first and second sides disposed over the first driver area and over the second doped region, wherein a portion of the first driver area adjacent the first side of the second gate structure is between the first side of the second gate structure and the second side of the first gate structure and wherein a portion of the first driver area adjacent the second side of the second gate structure is coupled for receiving a first source of operating potential.

14. The memory element of claim 13, wherein the first and second gate structures are substantially parallel to each other.

15. The memory element of claim 13, further including:
a third doped region, the third doped region of the first conductivity type and having a second pass transistor area and a second driver area;
a fourth doped region of the second conductivity type, the fourth doped region abutting the third doped region;
a third gate structure having first and second sides disposed over the second pass transistor area, wherein a first portion of the second pass transistor area adjacent the first side of the third gate structure is coupled to a second bit line; and
a fourth gate structure having first and second sides disposed over the second driver area and over the fourth doped region, wherein a portion of the second driver area adjacent the first side of the fourth gate structure is between the first side of the fourth gate structure and the second side of the third gate structure and wherein a portion of the second driver area adjacent the second side of the fourth gate structure is coupled for receiving the first source of operating potential.

16. The memory element of claim 15, wherein the first, second, third, and fourth gate structures are substantially parallel to each other.

17. The memory element of claim 15, wherein a width of the first driver area is greater than a width of the first pass transistor area and a width of the second driver area is greater than a width of the second pass transistor area.

18. The memory element of claim 15, wherein the first doped region cooperates with the second doped region to form a first rectangular shaped region having first and second opposing sides, and wherein a first U-shaped gap extends into the first rectangular shaped region from the first side and a first rectangular extension extends from the second side, and wherein the third doped region cooperates with the fourth doped region to form a second rectangular shaped region having first and second opposing sides, and wherein a second U-shaped gap extends into the second rectangular shaped region from the first side and a second rectangular extension extends from the second side.

19. The memory element of claim 15, wherein the first rectangular shaped region is adjacent to the second rectangular shaped region and wherein the first and second U-shaped gaps face opposite directions from each other, the first and second rectangular extensions extend in opposite directions from each other, and the first U-shaped region faces the same direction that the second rectangular extension extends.

20. The memory device of claim 11, wherein the substrate is a silicon-on-insulator substrate.

21. A method for manufacturing a memory device, comprising:
providing a substrate;
forming first, second, third, and fourth doped regions in the substrate, the first and third doped regions of a first conductivity type and the second and fourth doped regions of a second conductivity type, wherein the first and second doped regions abut each other and the third and fourth doped regions abut each other and are spaced apart from the first and second doped regions;
forming a first gate structure over a portion of the first doped region;
forming a second gate structure over another portion of the first doped region and over the second doped region;
implanting dopant of the second conductivity type into the portions of the first doped region adjacent the first and second gate structures;
implanting dopant of the first conductivity type into the portions of the second doped region adjacent the second gate structure;
forming a bit line metallization system over the substrate, the bit line metallization system electrically coupled to the portion of the first doped region adjacent a first side of the first gate structure; and
forming a word line metallization system over the bit line metallization system, the word line metallization system electrically coupled to the first gate structure.

22. The method of claim 21, further including:
forming a third gate structure over a portion of the third doped region;
forming a fourth gate structure over another portion of the third doped region and over the second doped region;
implanting dopant of the second conductivity type into the portions of the third doped region adjacent the third and fourth gate structures; and
implanting dopant of the first conductivity type into the portions of the fourth doped region adjacent the fourth gate structure.

23. The method of claim 22, wherein forming the first and second doped regions includes:
forming a first masking layer over the substrate, the masking layer having an opening exposing a first portion of the substrate; and
doping the first portion of the substrate with a dopant of the first conductivity type.

24. The method of claim 23, wherein forming the second doped region includes:
forming a second masking layer over the substrate, the second masking layer having an opening exposing a second portion of the substrate, the second portion being a sub-portion of the first portion of the substrate; and
doping the second portion of the substrate with a dopant of the second conductivity type.

25. The method of claim 24, wherein forming the first, second, third, and fourth gate structures comprises:
forming a layer of dielectric material over the substrate;
forming a layer of polysilicon over the layer of dielectric material; and
patterning the layer of polysilicon and the layer of dielectric material.

26. The method of claim 25, wherein forming the bit line metallization system includes:
forming a layer of dielectric material over the substrate;
forming a plurality of trenches in the layer of dielectric material; and
forming an electrically conductive material in the plurality of trenches.
